(19) United States
(12) Patent Application Publication
(10) Pub. No.: US 2026/0039087 A1
(43) Pub. Date: Feb. 5, 2026

(54) SURFACE-EMITTING QUANTUM CASCADE LASER

(71) Applicant: KABUSHIKI KAISHA TOSHIBA, Tokyo (JP)

(72) Inventors: Shinji SAITO, Yokohama Kanagawa (JP); Rei HASHIMOTO, Edogawa Tokyo (JP); Tsutomu KAKUNO, Fujisawa Kanagawa (JP); Kei KANEKO, Yokohama Kanagawa (JP); Tetsuya MIYAGAWA, Yokohama Kanagawa (JP)

(21) Appl. No.: 19/285,689

(22) Filed: Jul. 30, 2025

(30) Foreign Application Priority Data
Aug. 5, 2024 (JP) 2024-129009

(51) Int. Cl. H01S 5/183; H01S 5/11; H01S 5/34

(52) U.S. Cl. CPC H01S 5/1835; H01S 5/11; H01S 5/18305; H01S 5/3402

(57) ABSTRACT

According to one embodiment, a surface-emitting quantum cascade laser includes a first electrode, a second electrode, and a stacked body provided between the first electrode and the second electrode. The stacked body includes a first cladding layer, a second cladding layer, a light-emitting layer provided between the second cladding layer and a portion of the first cladding layer, and a photonic crystal layer including a plurality of structure bodies provided between the light-emitting layer and the second cladding layer. The stacked body includes a mesa region. The mesa region includes the portion of the first cladding layer and the light emitting layer. A planar shape of the mesa region in a first plane crossing a first direction from the first cladding layer to the second cladding layer includes a recess.

### CROSS-REFERENCE TO RELATED APPLICATIONS

This application is based upon and claims the benefit of priority from Japanese Patent Application No. 2024-129009, filed on Aug. 5, 2024; the entire contents of which are incorporated herein by reference.

### FIELD

Embodiments described herein relate generally to a surface-emitting quantum cascade laser.

### BACKGROUND

For example, there is a surface-emitting quantum cascade laser including a photonic crystal. It is desirable to improve the characteristics of the surface-emitting quantum cascade laser.

### BRIEF DESCRIPTION OF THE DRAWINGS

FIG. 1 is a schematic view illustrating a surface-emitting quantum cascade laser according to the first embodiment;

FIG. 2 is a schematic view illustrating the surface-emitting quantum cascade laser according to the first embodiment;

FIG. 3 is a schematic view illustrating a surface-emitting quantum cascade laser according to the first embodiment;

FIG. 4 is a schematic plan view illustrating a part of the surface-emitting quantum cascade laser according to the first embodiment;

FIG. 5 is a schematic diagram illustrating the characteristics of the surface-emitting quantum cascade laser according to the first embodiment;

FIG. 6 is schematic plan view illustrating a part of the surface-emitting quantum cascade laser according to the first embodiment.

FIG. 7 is a schematic plan view illustrating a part of the surface-emitting quantum cascade laser according to the first embodiment;

FIG. 8 is a schematic plan view illustrating a part of the surface-emitting quantum cascade laser according to the first embodiment;

FIG. 9 is a schematic plan view illustrating a part of the surface-emitting quantum cascade laser according to the first embodiment;

FIG. 10 is a schematic plan view illustrating a part of the surface-emitting quantum cascade laser according to the first embodiment;

FIG. 11 is a schematic plan view illustrating a part of the surface-emitting quantum cascade laser according to the first embodiment;

FIG. 12 is a schematic plan view illustrating a part of the surface-emitting quantum cascade laser according to the first embodiment;

FIG. 13 is a schematic plan view illustrating a part of the surface-emitting quantum cascade laser according to the first embodiment; and

FIG. 14 is a schematic plan view illustrating a part of the surface-emitting quantum cascade laser according to the first embodiment.

### DETAILED DESCRIPTION

According to one embodiment, a surface-emitting quantum cascade laser includes a first electrode, a second electrode, and a stacked body provided between the first electrode and the second electrode. The stacked body includes a first cladding layer, a second cladding layer, a light-emitting layer provided between the second cladding layer and a portion of the first cladding layer, and a photonic crystal layer including a plurality of structure bodies provided between the light-emitting layer and the second cladding layer. The stacked body includes a mesa region. The mesa region includes the portion of the first cladding layer and the light emitting layer. A planar shape of the mesa region in a first plane crossing a first direction from the first cladding layer to the second cladding layer includes a recess.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

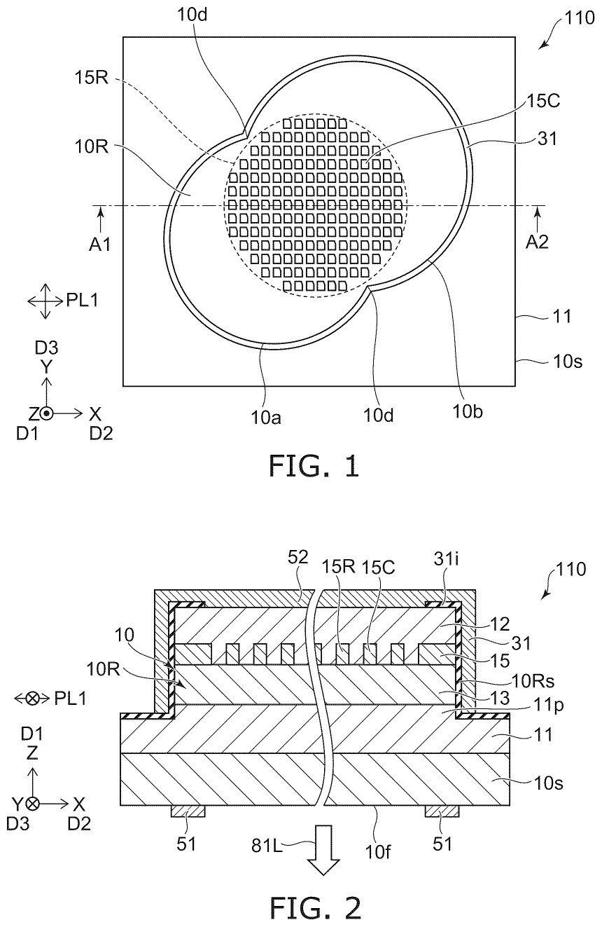

FIGS. 1 to 3 are schematic views illustrating a surface-emitting quantum cascade laser according to the first embodiment.

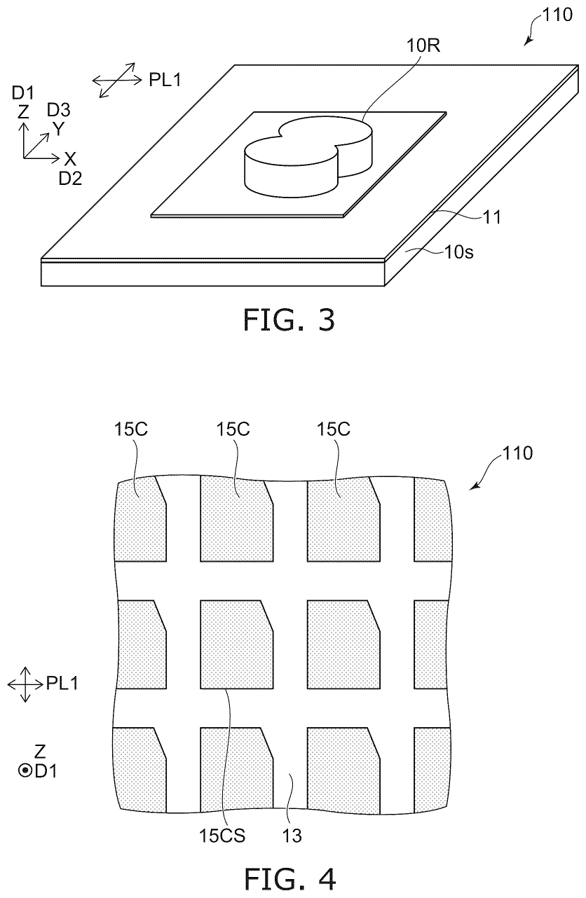

FIG. 1 is a plan view. FIG. 2 is a cross-sectional view corresponding to a cross section along the line A1-A2 in FIG. 1. FIG. 3 is a perspective view.

FIG. 4 is a schematic plan view illustrating a part of the surface-emitting quantum cascade laser according to the first embodiment.

As shown in FIGS. 1 to 3, a surface-emitting quantum cascade laser 110 according to the embodiment includes a first electrode 51, a second electrode 52, and a stacked body 10. The stacked body 10 is provided between the first electrode 51 and the second electrode 52.

The stacked body 10 includes a first cladding layer 11, a second cladding layer 12, a light-emitting layer 13, and a photonic crystal layer 15. The light-emitting layer 13 is provided between a portion 11p of the first cladding layer 11 and the second cladding layer 12. The photonic crystal layer 15 is provided between the light-emitting layer 13 and the second cladding layer 12. The photonic crystal layer 15 includes a plurality of structure bodies 15C.

As shown in FIG. 1, the stacked body 10 may include a substrate 10s. The substrate 10s is provided between a first electrode 51 and a first cladding layer 11. The substrate 10s includes a first substrate face 10f. For example, the first electrode 51 is provided on the first substrate face 10f.

As shown in FIG. 2, a first direction D1 from the first cladding layer 11 to the second cladding layer 12 is defined as an Z-axis direction. One direction perpendicular to the Z-axis direction is defined as an X-axis direction. A direction perpendicular to the Z-axis direction and the X-axis direction is defined as a Y-axis direction.

A portion 11p of the first cladding layer 11 and the light-emitting layer 13 are along a first plane PL1 crossing the first direction D1. The first plane PL1 is an X-Y plane. At least a part of the second cladding layer 12 is along the first plane PL1. The first plane PL1 is substantially parallel to a second direction D2 crossing the first direction D1. The first plane PL1 is substantially parallel to a third direction D3. The second direction D2 is, for example, the X-axis direction. The third direction D3 crosses a plane including the first direction D1 and the second direction. The third direction D3 is, for example, the Y-axis direction.

A part of the second cladding layer 12 is provided between the plurality of structure bodies 15C. The second cladding layer 12 contacts the plurality of structure bodies 15C. The refractive index of the second cladding layer 12 is different from the refractive index of the plurality of structure bodies 15C. For example, the refractive index of the second cladding layer 12 is lower than the refractive index of the plurality of structure bodies 15C. For example, the size of the plurality of structure bodies 15C is substantially equal to the wavelength of the light emitted from the light-emitting layer 13. Light is controlled in the plurality of structure bodies 15C.

For example, when a voltage is applied between the first electrode 51 and the second electrode 52, light is emitted from the light-emitting layer 13. The light is controlled by the photonic crystal layer 15 which includes the plurality of structure bodies 15C, and is emitted, for example, to the outside from the first substrate face 10f. The first substrate face 10f is, for example, a light emission face. The emitted light 81L from the surface-emitting quantum cascade laser 110 is emitted from a planar region.

As shown in FIGS. 1 and 2, for example, a region in which the plurality of structure bodies 15C are provided is defined as photonic region 15R. The first substrate face 10f includes a region overlapping the photonic region 15R in the Z-axis direction. The light is emitted from the region overlapping the photonic region 15R.

As shown in FIG. 2, the stacked body 10 includes a mesa region 10R. The mesa region 10R includes a portion 11p of the first cladding layer 11 and the light-emitting layer 13. The mesa region 10R is, for example, a current confinement region. By confining the current, light emission with high efficiency can be obtained. The mesa region 10R may further include a second cladding layer 12.

As shown in FIG. 1, the planar shape of the mesa region 10R in the first plane PL1 includes a recess 10d. Thereby, light with a substantially single wavelength can be obtained with high efficiency. According to the embodiment, a surface-emitting quantum cascade laser with improved characteristics can be provided.

For example, as shown in FIG. 2, the mesa region 10R includes a mesa side face 10Rs. The mesa side face 10Rs crosses the first plane PL1. A part of the light emitted from the light-emitting layer 13 is reflected by the mesa side face 10Rs and returns to the region corresponding to the photonic region 15R. For example, a reference example is considered in which two faces of the mesa side face 10Rs facing each other in the first plane PL1 are substantially parallel. In this reference example, light is repeatedly reflected between these two faces. This results in, for example, a Fabry-Perot mode. For example, a multimode is generated. In this case, the light emitted to the outside includes light with a dominant wavelength and light with a wavelength different from the dominant wavelength. For example, in one application, the light obtained from the surface-emitting quantum cascade laser 110 is used for analysis, etc. In this case, the light is required to have a single wavelength.

In the embodiment, the planar shape of the mesa region 10R on the first plane PL1 includes a recess 10d. For example, the direction of light reflected by the mesa side face 10Rs of the mesa region 10R is changed by the mesa side face 10Rs, which includes the recess 10d. This changes the optical path length and the propagation path of the light, suppressing oscillation due to repeated reflections. This allows light of a substantially single wavelength to be obtained with high efficiency.

As shown in FIG. 2, the surface-emitting quantum cascade laser 110 may further include a reflective film 31. A direction from the mesa side face 10Rs to the reflective film 31 crosses the first plane PL1. The reflectance of the reflective film 31 at the wavelength of the light emitted from the light-emitting layer 13 is higher than the reflectance of the first cladding layer 11 at the wavelength. By providing the reflective film 31, it is suppressed that the light emitted from the light-emitting layer 13 emits to the outside from the mesa side face 10Rs. High efficiency is easily achieved.

Light emitted from the light-emitting layer 13 and traveling along the X-Y plane is reflected by the reflective film 31 and returns to the region corresponding to the photonic region 15R. When the reflective film 31 is provided, for example, in a rectangular resonator optical structure body without a recess, the Fabry-Perot mode occurs more prominently. In the embodiment, the planar shape of the mesa region 10R in the first plane PL1 includes the recess 10d. Therefore, the traveling direction of the light is changed by the mesa side face 10Rs including the recess 10d. Thereby, the optical path length and the propagation path of the light is changed and oscillation due to repeated reflection is suppressed. As a result, light of a substantially single wavelength can be obtained with high efficiency.

For example, the planar shape of the mesa region 10R corresponds to the planar shape of the mesa side face 10Rs. In the embodiment, for example, the planar shape (outer edge) of the mesa region 10R does not have vertical reflecting faces at positions facing each other. Thereby, Fabry-Perot modes due to repeated reflections is effectively suppressed.

As shown in FIG. 1, the planar shape of the mesa region 10R includes a first outer edge portion 10a and a second outer edge portion 10b. The recess 10d is provided between the first outer edge portion 10a and the second outer edge portion 10b. For example, the curvature of the first outer edge portion 10a is different from the curvature of the second outer edge portion 10b. The Fabry-Perot mode is effectively suppressed.

For example, the first outer edge portion 10a and the second outer edge portion 10b are convex in a direction from the inside to the outside of the planar shape. The recess 10d is concave in a direction from the outside to the inside of the planar shape. For example, the recess 10d is provided between plurality of regions of the planar shape. The recess 10d is, for example, a recess portion.

As shown in FIG. 2, the reflective film 31 may be continuous with the second electrode 52. The reflective film 31 may include gold. The second electrode 52 may include gold. The second electrode 52 may include Ni and gold. The second electrode 52 may include a Ni film and a gold film. For example, low electrical resistance and high reflectance can be obtained.

As shown in FIG. 2, the surface-emitting quantum cascade laser 110 may include an insulating film 31i. The insulating film 31i is provided between the mesa side face 10Rs and the reflective film 31. The insulating film 31i includes, for example, silicon and oxygen. The insulating film 31i includes, for example, silicon oxide. In FIG. 1, the insulating film 31i is omitted. FIG. 3 shows a schematic example of the mesa region 10R.

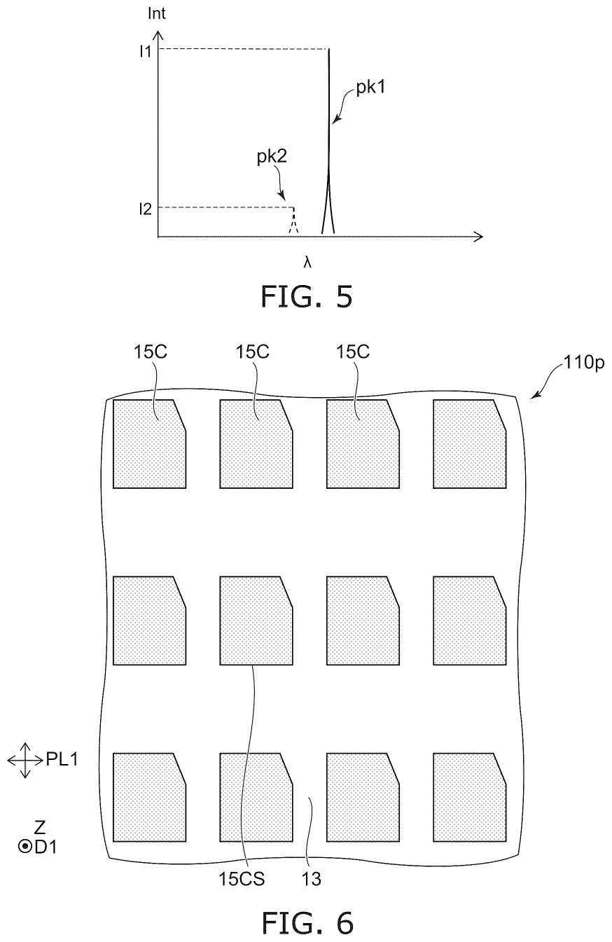

FIG. 5 is a schematic diagram illustrating the characteristics of the surface-emitting quantum cascade laser according to the first embodiment.

FIG. 5 illustrates the characteristics of the emitted light 81L (see FIG. 2) emitted from the surface-emitting quantum cascade laser 110. The horizontal axis of FIG. 5 is the wavelength λ. The vertical axis of FIG. 5 is the light intensity Int.

As shown in FIG. 5, the emitted light 81L emitted from the surface-emitting quantum cascade laser 110 includes a first peak pk1. In one example, the emitted light 81L does not include any other peaks, for example, except for the first peak pk1. In another example, the intensity 12 of the other peak (for example, the second peak pk2) is 1/100 or less of the intensity I1 of the first peak pk1. Thus, in the embodiment, the emitted light 81L with substantially single-peak is obtained.

FIG. 4 illustrates the plurality of structure bodies 15C. In the example of FIG. 4, the structure body shape 15CS on the first plane PL1 of one of the plurality of structure bodies 15C is substantially pentagonal. In an embodiment, the structure body shape 15CS may be, for example, a polygon including five or more sides, a circle, or a flat circle (including an ellipse). In the example of FIG. 4, the plurality of structure bodies 15C have a square lattice arrangement.

FIGS. 6 and 7 are schematic plan views illustrating a part of the surface-emitting quantum cascade laser according to the first embodiment.

These figures illustrate the plurality of structure bodies 15C. As shown in FIG. 6, in a surface-emitting quantum cascade laser 110p according to the embodiment, the plurality of structure bodies 15C have a rectangular lattice arrangement. As shown in FIG. 7, in a surface-emitting quantum cascade laser 110q according to the embodiment, the plurality of structure bodies 15C have a triangular lattice arrangement. Thus, in the embodiment, the plurality of structure bodies 15C may be arranged in any of a square lattice arrangement, a rectangular lattice arrangement, and a triangular lattice arrangement. The plurality of structure bodies 15C are arranged two-dimensionally along the first plane PL1. In one direction along the first plane PL1, the plurality of structure bodies 15C are arranged at substantially one pitch.

Below, several examples of the planar shape of the mesa region 10R in the first plane PL1 will be described.

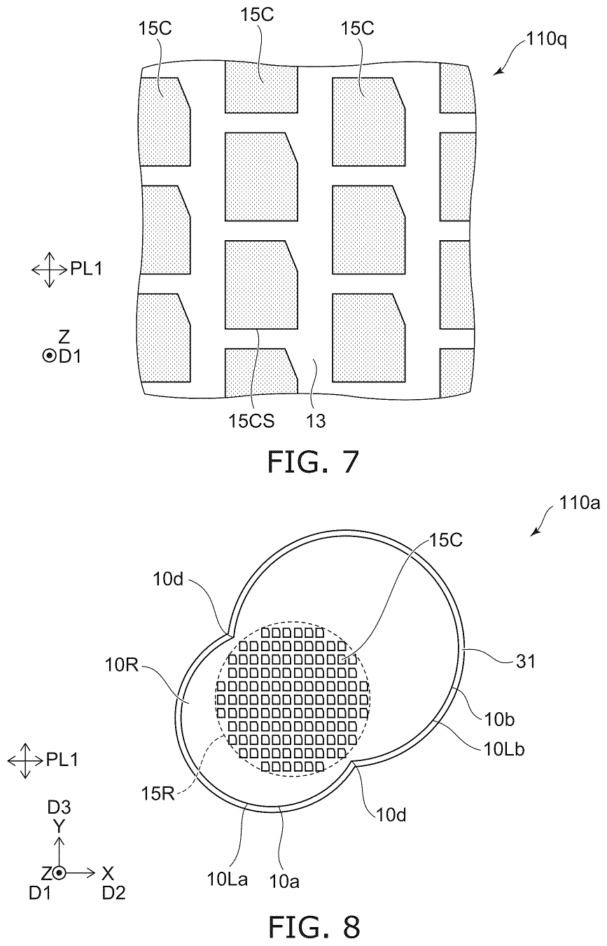

FIGS. 8 to 14 are schematic plan views illustrating a part of the surface-emitting quantum cascade laser according to the first embodiment.

These figures illustrate the planar shape of the mesa region 10R in the first plane PL1.

As shown in FIG. 8, in a surface-emitting quantum cascade laser 110a according to the embodiment, the planar shape of the mesa region 10R includes a recess 10d. The recess 10d is between the first outer edge portion 10a and the second outer edge portion 10b. The curvature of the first outer edge portion 10a is different from the curvature of the second outer edge portion 10b. In this example, the center of the photonic region 15R in which the plurality of structure bodies 15C are provided is different from the center of the planar shape of the mesa region 10R. An eccentric configuration is applied.

As shown in FIG. 8, the planar shape of the mesa region 10R includes a first curve 10La and a second curve 10Lb. The first curve 10La may be, for example, at least a part of the first outer edge portion 10a. The second curve 10Lb may be, for example, at least a part of the second outer edge portion 10b. The first curve 10La has a first curvature. The second curve 10Lb has a second curvature that is different from the first curvature. With this configuration, the Fabry-Perot mode is also suppressed.

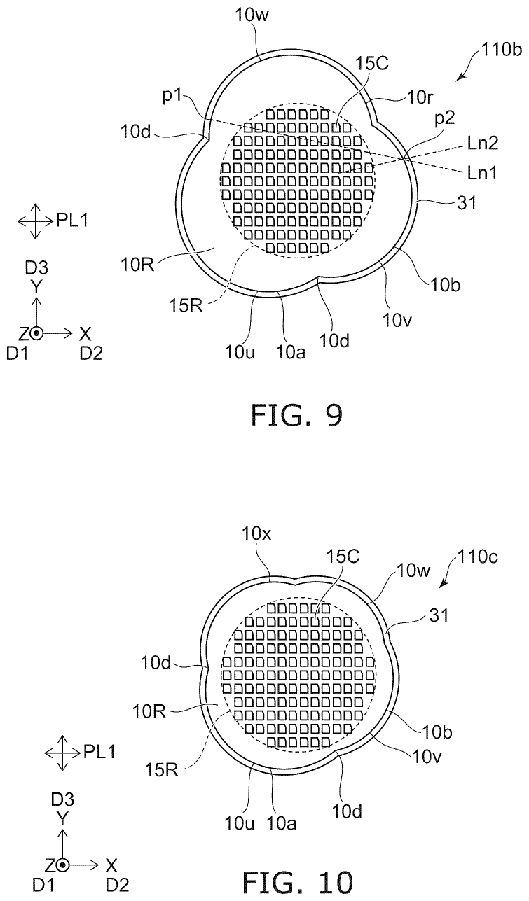

As shown in FIG. 9, in a surface-emitting quantum cascade laser 110b according to the embodiment, the planar shape of the mesa region 10R includes a first circular arc 10u, a second circular arc 10v, and a third circular arc 10w. The position of the center of the first circular arc 10u is different from the position of the center of the second circular arc 10v, and is different from the position of the center of the third circular arc 10w. The position of the center of the second circular arc 10v is different from the position of the center of the third circular arc 10w. In this example as well, the Fabry-Perot mode is suppressed.

As shown in FIG. 10, in a surface-emitting quantum cascade laser 110c according to the embodiment, the planar shape of the mesa region 10R includes a first circular arc 10u, a second circular arc 10v, a third circular arc 10w, and a fourth circular arc 10x. The positions of the centers of these arcs are different from one another. The planar shape of the mesa region 10R is asymmetric. The planar shape of the mesa region 10R does not have, for example, an axis of symmetry. In this example, the Fabry-Perot mode is also suppressed. In this example, the center of the photonic region 15R is different from the center of the planar shape of the mesa region 10R. An asymmetric configuration is applied.

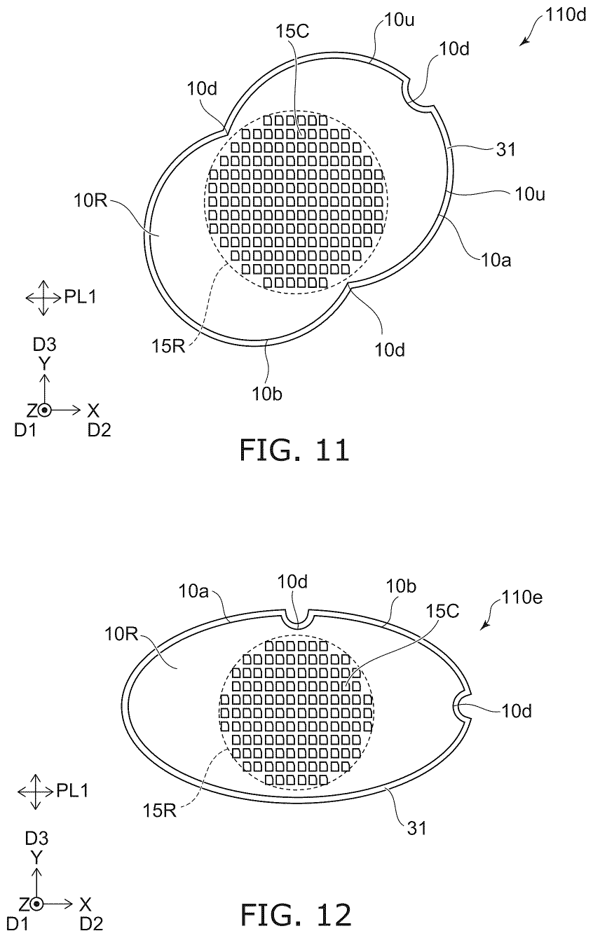

As shown in FIG. 11, in a surface-emitting quantum cascade laser 110d according to the embodiment, the planar shape of the mesa region 10R includes recesses 10d. In this example, the number of recesses 10d is three. One of the recesses 10d is provided between a plurality of first circular arcs 10u. In this example as well, the Fabry-Perot mode is suppressed.

As shown in FIG. 12, in a surface-emitting quantum cascade laser 110e according to the embodiment, the planar shape of the mesa region 10R includes recesses 10d. In this example as well, the Fabry-Perot mode is suppressed.

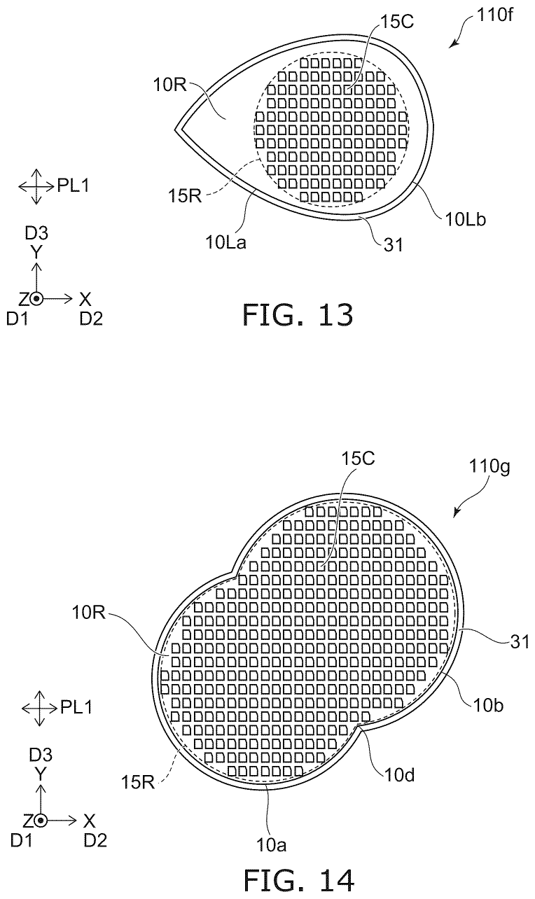

As shown in FIG. 13, in a surface-emitting quantum cascade laser 110f according to the embodiment, the planar shape of the mesa region 10R includes a first curve 10La and a second curve 10Lb. The first curve 10La has a first curvature. The second curve 10Lb has a second curvature different from the first curvature. This configuration also suppresses the Fabry-Perot mode. In this example, at least one of the first curve 10La and the second curve 10Lb is at least a part of a quadratic function. For example, at least one of the first curve 10La and the second curve 10Lb may include a part of a polynomial function. In this example, the center of the photonic region 15R is different from the center of the planar shape of the mesa region 10R. An asymmetric configuration is applied.

In the examples of FIG. 1 and FIGS. 8 to 13, the planar shape of the mesa region 10R may include an area that does not overlap the photonic region 15R in the first direction D1.

As shown in FIG. 14, in a surface-emitting quantum cascade laser 110g according to the embodiment, the planar shape of the mesa region 10R includes the recesses 10d. In this example, the planar shape of the mesa region 10R substantially coincides with the photonic region 15R in which the plurality of structure bodies 15C are provided. In such a configuration, oscillation due to repeated reflection does not substantially occur, and light is efficiently emitted to the outside from the region corresponding to the photonic region 15R. Fabry-Perot modes are suppressed, and high-intensity single-wavelength light is obtained.

Thus, in the embodiment, the planar shape of the mesa region 10R on the first plane PL1 may satisfy at least one of a first condition, a second condition, a third condition, or a fourth condition below.

In the first condition, the planar shape includes a first curve 10La having a first curvature and a second curve 10Lb having a second curvature different from the first curvature (see FIG. 8, etc.).

In the second condition, the planar shape includes a first circular arc 10u, a second circular arc 10v, and a third circular arc 10w (see FIG. 9, etc.). A position of the center of the first circular arc 10u is different from a position of the center of the second circular arc 10v, and is different from a position of the center of the third circular arc 10w. The position of the center of the second circular arc 10v is different from the position of the center of the third circular arc 10w.

In the third condition, the planar shape includes a recess 10d (see FIGS. 1 and 8, etc.).

In the fourth condition, the planar shape coincides with the photonic region 15R in which the plurality of structure bodies 15C are provided (see FIG. 14).

When the planar shape satisfies at least one of the first condition, the second condition, the third condition, or the fourth condition, the Fabry-Perot mode is suppressed. For example, high-intensity light with a single wavelength can be obtained.

When the planar shape satisfies the third condition, the planar shape may include the first outer edge portion 10a and the second outer edge portion 10b. The recess 10d is provided between the first outer edge portion 10a and the second outer edge portion 10b. For example, the curvature of the first outer edge portion 10a is different from the curvature of the second outer edge portion 10b.

As already explained, the first outer edge portion 10a and the second outer edge portion 10b are convex in the direction from the inside to the outside of the planar shape. The recess 10d is concave in the direction from the outside to the inside. For example, the recess 10d is provided between plurality of regions of the planar shape.

For example, when the planar shape satisfies the first condition, the first curve 10La may be a part of the outer edge of the first circle. The second curve 10Lb may be a part of the outer edge of the second circle. The first position of the first center of the first circle is different from the second position of the second center of the second circle. The centers of plurality of circles are provided at the shifted positions.

For example, when the planar shape satisfies the first condition, at least one of the first curve 10La and the second curve 10Lb may include a part of a polynomial function. For example, the polynomial function may include a quadratic function.

For example, when the planar shape of the mesa region 10R satisfies at least one of the first condition, the second condition, or the third condition, the planar shape may include a region that does not overlap with the photonic region 15R in the first direction D1.

The configurations described with reference to FIGS. 4, 6 and 7 may be applied to the surface-emitting quantum cascade lasers 110a to 110g.

As shown in FIG. 9, the outer edge portion 10r of the planar shape of the mesa region 10R includes a first portion p1 and a second portion p2. A first normal Ln1 at the first portion p1 of the outer edge portion 10r passes through the second portion p2. A second normal Ln2 at the second portion p2 of the outer edge portion 10r is inclined with respect to the first normal Ln1. For example, the second normal Ln2 is non-parallel to the first normal Ln1. In such a configuration, oscillation due to repeated reflection is suppressed.

In the embodiment, the light-emitting layer 13 emits light based on intersubband transition. In one example, the first cladding layer 11 and the second cladding layer 12 include In, P, and As. On the other hand, the plurality of structure bodies 15C include In, Ga, and As. The surface-emitting quantum cascade laser according to the embodiment is, for example, a QCL (Quantum Cascade Laser). The wavelength of the light emitted from the surface-emitting quantum cascade laser may be, for example, not less than 4 μm and not more than 11 μm. The surface-emitting quantum cascade laser can be used, for example, as a light source for gas analysis.

In the embodiment, for example, repeated reflection is suppressed. By suppressing repeated reflection, for example, Fabry-Perot modes are suppressed. For example, a vertically opposing reflective face (for example, mesa side face 10Rs or reflective film 31) is substantially not provided. Or, the area of the vertically opposing reflective face is reduced.

In the embodiment, for example, it is preferable that there is little optical absorption loss. For example, it is preferable that the distance along the first plane PL1 between the mesa side face 10Rs and the photonic region 15R is short. It is preferable that the reflectance of the reflective film 31 is high. In the embodiment, for example, it is preferable that the planar shape of the mesa region 10R does not include a dead end. Light is extracted efficiently. The planar shape of the mesa region 10R may be formed by photolithography and etching. The etching includes dry etching, etc.

The outer edge of the planar shape of the mesa region 10R may be, for example, curved based on plurality of fine straight line segments.

The embodiments may include the following Technical proposals:

### Technical Proposal 1

A surface-emitting quantum cascade laser, comprising:
a first electrode;
a second electrode; and
a stacked body provided between the first electrode and the second electrode,
the stacked body including
   a first cladding layer,
   a second cladding layer,
   a light-emitting layer provided between the second cladding layer and a portion of the first cladding layer, and
   a photonic crystal layer including a plurality of structure bodies provided between the light-emitting layer and the second cladding layer,
the stacked body including a mesa region,
the mesa region including the portion of the first cladding layer and the light emitting layer, and
a planar shape of the mesa region in a first plane crossing a first direction from the first cladding layer to the second cladding layer includes a recess.

### Technical Proposal 2

The surface-emitting quantum cascade laser according to Technical proposal 1, wherein
a planar shape includes a first outer edge portion and a second outer edge portion,
the recess is between the first outer edge portion and the second outer edge portion, and
a curvature of the first outer edge portion is different from a curvature of the second outer edge portion.

### Technical Proposal 3

The surface-emitting quantum cascade laser according to Technical proposal 2, wherein
the first outer edge portion and the second outer edge portion are convex in a direction from an inside to an outside of the planar shape, and
the recess is concave in a direction from the outside to the inside.

### Technical Proposal 4

A surface-emitting quantum cascade laser, comprising:
a first electrode;
a second electrode; and
a stacked body provided between the first electrode and the second electrode,
the stacked body including
   a first cladding layer,
   a second cladding layer,
   a light-emitting layer provided between the second cladding layer and a portion of the first cladding layer, and
   a photonic crystal layer including a plurality of structure bodies provided between the light-emitting layer and the second cladding layer,
the stacked body including a mesa region,
the mesa region including a portion of the first cladding layer and the light emitting layer, and
a planar shape of the mesa region in a first plane crossing a first direction from the first cladding layer to the second cladding layer satisfying at least one of a first condition, a second condition, a third condition, or a fourth condition,
in the first condition, the planar shape including a first curve having a first curvature and a second curve having a second curvature different from the first curvature,
in the second condition, the planar shape including a first circular arc, a second circular arc, and a third circular arc, a position of a center of the first circular arc being different from a position of a center of the second circular arc and being different from a position of a center of the third circular arc, the position of the center of the second circular arc being different from the position of the center of the third circular arc,
in the third condition, the planar shape including a recess, and
in the fourth condition, the planar shape coinciding with a photonic region in which the plurality of structure bodies are provided.

### Technical Proposal 5

The surface-emitting quantum cascade laser according to Technical proposal 4, wherein
the planar shape satisfies the third condition,
the planar shape includes a first outer edge portion and a second outer edge portion,
the recess is between the first outer edge portion and the second outer edge portion,
a curvature of the first outer edge portion is different from a curvature of the second outer edge portion.

### Technical Proposal 6

The surface-emitting quantum cascade laser according to Technical proposal 5, wherein
the first outer edge portion and the second outer edge portion are convex in a direction from an inside to an outside of the planar shape, and
the recess is concave in a direction from the outside to the inside.

### Technical Proposal 7

The surface-emitting quantum cascade laser according to Technical proposal 4, wherein
the planar shape satisfies the first condition,
the first curve is a part of an outer edge of a first circle,
the second curve is a part of an outer edge of a second circle, and
a first position of a first center of the first circle is different from a second position of a second center of the second circle.

### Technical Proposal 8

The surface-emitting quantum cascade laser according to Technical proposal 4, wherein
the planar shape satisfies the first condition, and
at least one of the first curve and the second curve includes a portion of a polynomial function.

### Technical Proposal 9

The surface-emitting quantum cascade laser according to Technical proposal 4, wherein
the planar shape satisfies at least one of the first condition, the second condition, or the third condition, and
the planar shape includes a region not overlapping the photonic region in the first direction.

### Technical Proposal 10

The surface-emitting quantum cascade laser according to any one of Technical proposals 1-9, further comprising
a reflective film,
the mesa region further includes a mesa side face crossing the first plane,
a direction from the mesa side face to the reflective film crossing the first plane,
a reflectance of the reflective film at a wavelength of light emitted from the light emitting layer is higher than a reflectance of the first cladding layer at the wavelength.

### Technical Proposal 11

The surface-emitting quantum cascade laser according to Technical proposal 10, wherein
the reflective film is continuous with the second electrode.

### Technical Proposal 12

The surface-emitting quantum cascade laser according to Technical proposal 10 or 11, wherein
the reflective film includes gold.

### Technical Proposal 13

The surface-emitting quantum cascade laser according to any one of Technical proposals 10-12, further comprising;
an insulating film provided between the mesa side face and the reflective film.

### Technical Proposal 14

The surface-emitting quantum cascade laser according to any one of Technical proposals 1-13, wherein
the plurality of structure bodies are arranged in any one of a square lattice array, a rectangular lattice array, and a triangular lattice array.

### Technical Proposal 15

The surface-emitting quantum cascade laser according to any one of Technical proposals 1-14, wherein
light emitted from the surface-emitting quantum cascade laser includes a first peak and does not include any other peaks except the first peak, or
an intensity of the other peaks is 1/100 or less of an intensity of the first peak.

### Technical Proposal 16

The surface-emitting quantum cascade laser according to any one of Technical proposals 1-15, wherein
an outer edge of the planar shape includes a first portion and a second portion,
a first normal at the first portion of the outer edge passes through the second portion, and
a second normal at the second portion of the outer edge is inclined with respect to the first normal.

### Technical Proposal 17

The surface-emitting quantum cascade laser according to any one of Technical proposals 1-16, wherein
the light emitting layer emits light based on an intersubband transition.

### Technical Proposal 18

The surface-emitting quantum cascade laser according to any one of Technical proposals 1-17, wherein
the first cladding layer and the second cladding layer include In, P, and As.

### Technical Proposal 19

The surface-emitting quantum cascade laser according to Technical proposal 18, wherein
the plurality of structure bodies include In, Ga, and As.

### Technical Proposal 20

The surface-emitting quantum cascade laser according to any one of Technical proposals 1-19, wherein
a shape of one of the plurality of structure bodies on the first plane is a polygon having five or more sides, a circle, or an flat circle.

According to the embodiment, a surface-emitting quantum cascade laser with improved characteristics can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in surface-emitting quantum cascade lasers such as electrodes, stacked bodies, cladding layers, light-emitting layers, photonic crystal layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all surface-emitting quantum cascade lasers practicable by an appropriate design modification by one skilled in the art based on the surface-emitting quantum cascade lasers described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A surface-emitting quantum cascade laser, comprising:
a first electrode;
a second electrode; and
a stacked body provided between the first electrode and the second electrode,
the stacked body including
a first cladding layer,
a second cladding layer,
a light-emitting layer provided between the second cladding layer and a portion of the first cladding layer, and
a photonic crystal layer including a plurality of structure bodies provided between the light-emitting layer and the second cladding layer,
the stacked body including a mesa region,
the mesa region including the portion of the first cladding layer and the light emitting layer, and
a planar shape of the mesa region in a first plane crossing a first direction from the first cladding layer to the second cladding layer includes a recess.

2. The surface-emitting quantum cascade laser according to claim 1, wherein
a planar shape includes a first outer edge portion and a second outer edge portion,
the recess is between the first outer edge portion and the second outer edge portion, and
a curvature of the first outer edge portion is different from a curvature of the second outer edge portion.

3. The surface-emitting quantum cascade laser according to claim 2, wherein
the first outer edge portion and the second outer edge portion are convex in a direction from an inside to an outside of the planar shape, and
the recess is concave in a direction from the outside to the inside.

4. A surface-emitting quantum cascade laser, comprising:
a first electrode;
a second electrode; and
a stacked body provided between the first electrode and the second electrode,
the stacked body including
a first cladding layer,
a second cladding layer,
a light-emitting layer provided between the second cladding layer and a portion of the first cladding layer, and
a photonic crystal layer including a plurality of structure bodies provided between the light-emitting layer and the second cladding layer,
the stacked body including a mesa region,
the mesa region including a portion of the first cladding layer and the light emitting layer, and
a planar shape of the mesa region in a first plane crossing a first direction from the first cladding layer to the second cladding layer satisfying at least one of a first condition, a second condition, a third condition, or a fourth condition,
in the first condition, the planar shape including a first curve having a first curvature and a second curve having a second curvature different from the first curvature,
in the second condition, the planar shape including a first circular arc, a second circular arc, and a third circular arc, a position of a center of the first circular arc being different from a position of a center of the second circular arc and being different from a position of a center of the third circular arc, the position of the center of the second circular arc being different from the position of the center of the third circular arc,
in the third condition, the planar shape including a recess, and
in the fourth condition, the planar shape coinciding with a photonic region in which the plurality of structure bodies are provided.

5. The surface-emitting quantum cascade laser according to claim 4, wherein
the planar shape satisfies the third condition,
the planar shape includes a first outer edge portion and a second outer edge portion,
the recess is between the first outer edge portion and the second outer edge portion,
a curvature of the first outer edge portion is different from a curvature of the second outer edge portion.

6. The surface-emitting quantum cascade laser according to claim 5, wherein
the first outer edge portion and the second outer edge portion are convex in a direction from an inside to an outside of the planar shape, and
the recess is concave in a direction from the outside to the inside.

7. The surface-emitting quantum cascade laser according to claim 4, wherein
the planar shape satisfies the first condition,
the first curve is a part of an outer edge of a first circle,
the second curve is a part of an outer edge of a second circle, and
a first position of a first center of the first circle is different from a second position of a second center of the second circle.

8. The surface-emitting quantum cascade laser according to claim 4, wherein
the planar shape satisfies the first condition, and
at least one of the first curve and the second curve includes a portion of a polynomial function.

9. The surface-emitting quantum cascade laser according to claim 4, wherein
the planar shape satisfies at least one of the first condition, the second condition, or the third condition, and
the planar shape includes a region not overlapping the photonic region in the first direction.

10. The surface-emitting quantum cascade laser according to claim 1, further comprising
a reflective film,
the mesa region further includes a mesa side face crossing the first plane,
a direction from the mesa side face to the reflective film crossing the first plane,
a reflectance of the reflective film at a wavelength of light emitted from the light emitting layer is higher than a reflectance of the first cladding layer at the wavelength.

11. The surface-emitting quantum cascade laser according to claim 10, wherein
the reflective film is continuous with the second electrode.

12. The surface-emitting quantum cascade laser according to claim 10, wherein
the reflective film includes gold.

13. The surface-emitting quantum cascade laser according to claim 10, further comprising;
an insulating film provided between the mesa side face and the reflective film.

14. The surface-emitting quantum cascade laser according to claim 1, wherein
the plurality of structure bodies are arranged in any one of a square lattice array, a rectangular lattice array, and a triangular lattice array.

15. The surface-emitting quantum cascade laser according to claim 1, wherein
light emitted from the surface-emitting quantum cascade laser includes a first peak and does not include any other peaks except the first peak, or
an intensity of the other peaks is 1/100 or less of an intensity of the first peak.

16. The surface-emitting quantum cascade laser according to claim 1, wherein
an outer edge of the planar shape includes a first portion and a second portion,
a first normal at the first portion of the outer edge passes through the second portion, and
a second normal at the second portion of the outer edge is inclined with respect to the first normal.

17. The surface-emitting quantum cascade laser according to claim 1, wherein
the light emitting layer emits light based on an intersubband transition.

18. The surface-emitting quantum cascade laser according to claim 1, wherein
the first cladding layer and the second cladding layer include In, P, and As.

19. The surface-emitting quantum cascade laser according to claim 18, wherein
the plurality of structure bodies include In, Ga, and As.

20. The surface-emitting quantum cascade laser according to claim 1, wherein
a shape of one of the plurality of structure bodies on the first plane is a polygon having five or more sides, a circle, or an flat circle.
